(19) United States
(12) Patent Application Publication
(10) Pub. No.: US 2024/0304540 A1
(43) Pub. Date: Sep. 12, 2024

(54) SEMICONDUCTOR DEVICE AND MANUFACTURING METHOD OF SEMICONDUCTOR DEVICE

(71) Applicant: SK hynix Inc., Icheon-si Gyeonggi-do (KR)

(72) Inventor: Nam Jae LEE, Icheon-si Gyeonggi-do (KR)

(73) Assignee: SK hynix Inc., Icheon-si Gyeonggi-do (KR)

(21) Appl. No.: 18/348,211

(22) Filed: Jul. 6, 2023

(30) Foreign Application Priority Data
Mar. 7, 2023 (KR) 10-2023-0030162

(51) Int. Cl. H01L 23/522; H01L 21/768; H01L 23/528; H01L 23/532

(52) U.S. Cl. CPC H01L 23/5226; H01L 21/76804; H01L 21/76877; H01L 23/5283; H01L 23/53266

(57) ABSTRACT

A semiconductor device includes: a first interconnection structure; and a second interconnection structure including a first wiring part electrically connected to the first interconnection structure, a first hard mask pattern on the first wiring part, and a first via part connected to the first wiring part through the first hard mask pattern.

### CROSS-REFERENCE TO RELATED APPLICATION

This application claims priority under 35 U.S.C. § 119 (a) to Korean Patent Application No. 10-2023-0030162 filed on Mar. 7, 2023, in the Korean Intellectual Property Office, which is incorporated herein by reference in its entirety.

### BACKGROUND

### 1. Technical Field

Embodiments of the present disclosure generally relate to an electronic device, and more particularly, to a semiconductor device and a manufacturing method of the semiconductor device.

### 2. Related Art

A semiconductor device includes an interconnection such as wiring and a contact plug for an electrical connection between elements. Recently, to improve the operating speed, reliability, and the like of a semiconductor device, materials, structures, manufacturing methods, and the like of an interconnection are being developed.

### SUMMARY

In an embodiment, a semiconductor device may include: a first interconnection structure; and a second interconnection structure including a first wiring part electrically connected to the first interconnection structure, a first hard mask pattern on the first wiring part, and a first via part connected to the first wiring part through the first hard mask pattern.

In an embodiment, a manufacturing method of a semiconductor device may include: forming a first hard mask pattern on a first sacrificial layer; forming a first sacrificial pattern by etching the first sacrificial layer using the first hard mask pattern as an etching barrier; forming a second interlayer dielectric layer on the first sacrificial pattern; forming, on the second interlayer dielectric layer, a second sacrificial layer including a sacrificial via connected to the first sacrificial pattern through the second interlayer dielectric layer and the first hard mask pattern; forming a second hard mask pattern on the second sacrificial layer; forming a second sacrificial pattern including a sacrificial wiring by etching the second sacrificial layer using the second hard mask pattern as an etching barrier; forming a trench by removing the second sacrificial pattern and the first sacrificial pattern; and forming, in the trench, an interconnection structure including a first wiring part, a first via part connected to the first wiring part through the first hard mask pattern, and a second wiring part connected to the first via part.

### BRIEF DESCRIPTION OF THE DRAWINGS

FIG. 1 is a diagram illustrating the structure of a semiconductor device in accordance with an embodiment.

FIG. 2 is a diagram illustrating the structure of a semiconductor device in accordance with an embodiment.

FIGS. 3A, 3B, and 3C are diagrams illustrating the structure of a semiconductor device in accordance with an embodiment.

FIGS. 4A, 4B, 4C, 4D, 4E, 4F, and 4G are diagrams for describing a manufacturing method of a semiconductor device in accordance with an embodiment.

FIGS. 5A and 5B are diagrams for describing a manufacturing method of a semiconductor device in accordance with an embodiment.

### DETAILED DESCRIPTION

Various embodiments are directed to a semiconductor device having a stable structure and improved characteristics and a manufacturing method of the semiconductor device.

It is possible to provide, in an embodiment, a semiconductor device having a stable structure and improved reliability.

Hereafter, embodiments in accordance with the technical spirit of the present disclosure will be described with reference to the accompanying drawings. It will be understood that when an element or layer etc., is referred to as being “on,”“connected to” or “coupled to” another element or layer etc., it can be directly on, connected or coupled to the other element or layer etc., or intervening elements or layers etc., may be present. In contrast, when an element or layer etc., is referred to as being “directly on,”“directly connected to” or “directly coupled to” another element or layer etc., there are no intervening elements or layers etc., present. It will be understood that although the terms first, second, third etc. may be used herein to describe various elements, these elements should not be limited by these terms. These terms are only used to distinguish one element from another element, but not used to define only the element itself or to mean a particular sequence.

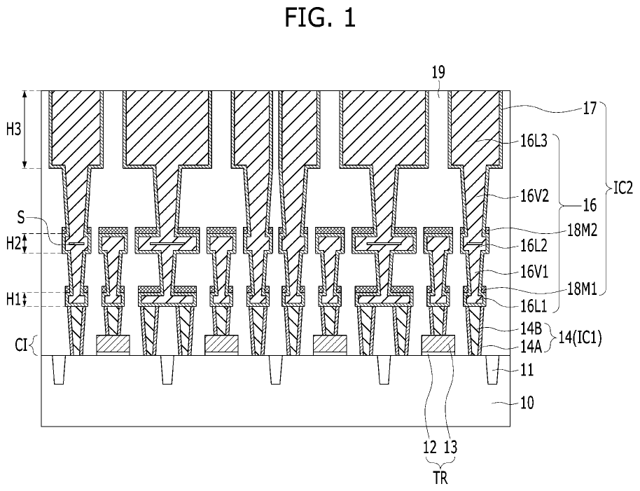

FIG. 1 is a diagram illustrating the structure of a semiconductor device in accordance with an embodiment.

Referring to FIG. 1, the semiconductor device may include a first interconnection structure IC1 and a second interconnection structure IC2. The semiconductor device may further include a substrate 10, an isolation layer 11, a circuit CI, or an interlayer dielectric layer 19, or a combination thereof.

The first interconnection structure IC1 may be located in the interlayer dielectric layer 19. The first interconnection structure IC1 may be used as a path for supplying a bias to the circuit CI or a cell array. In an embodiment, the circuit CI may be electrically connected to the first interconnection structure IC1. The first interconnection structure IC1 may include a via, or a wiring, or a combination thereof. The first interconnection structure IC1 may include a conductive material such as polysilicon or metal. As an example, the first interconnection structure IC1 may include a via 14, and the via 14 may include a first barrier layer 14A and a first metal layer 14B located in the first barrier layer 14A. The first barrier layer 14A may surround sidewalls and a bottom surface of the first metal layer 14B. In an embodiment, the first barrier layer 14A is for improving adhesion of the first metal layer 14B, and may include metal nitride such as titanium nitride. The first metal layer 14B may include metal such as tungsten (W) or molybdenum (Mo).

The circuit CI may be a peripheral circuit for driving the cell array. The circuit CI may include a page buffer, an X-decoder, a sense amplifier, and the like. As an example, the circuit CI may include a transistor TR. The transistor TR may include a gate insulating layer 12 and a gate electrode 13. An active region may be defined in the substrate 10 by the isolation layer 11, and the transistor TR may be located in the active region.

The second interconnection structure IC2 may be located in the interlayer dielectric layer 19. The second interconnection structure IC2 may be used as a path for supplying a bias to the circuit CI or the cell array, and may be electrically connected to the first interconnection structure IC1. The second interconnection structure IC2 may be directly connected to the circuit CI without passing through the first interconnection structure IC1.

The second interconnection structure IC2 may include a first wiring part 16L1, a first hard mask pattern 18M1, and a first via part 16V1. The first wiring part 16L1 may be directly connected to the first interconnection structure IC1. The first wiring part 16L1 may have a line shape extending in one direction. The first hard mask pattern 18M1 may be located on the first wiring part 16L1. The first hard mask pattern 18M1 may have substantially the same width as that of the first wiring part 16L1.

The first hard mask pattern 18M1 may be used as an anti-reflective layer, an etch stop layer, or an anti-reflective layer and an etch stop layer in a manufacturing process. The first hard mask pattern 18M1 may include oxide, nitride, silicon oxynitride (SiON), carbon, or the like. As an example, the first hard mask pattern 18M1 may include silicon oxynitride (SiON) and may be used as an anti-reflective layer and an etch stop layer.

The first via part 16V1 may be connected to the first wiring part 16L1 through the first hard mask pattern 18M1. The first via part 16V1 may pass through the first hard mask pattern 18M1. The first via part 16V1 may have a plug shape having a plane such as a circular shape, an elliptical shape, or a polygonal shape.

The second interconnection structure IC2 may further include a second wiring part 16L2, a second hard mask pattern 18M2, and a second via part 16V2. The second wiring part 16L2 may be connected to the first via part 16V1. The second wiring part 16L2 may have a line shape extending in one direction. The second hard mask pattern 18M2 may be located on the second wiring part 16L2. The second hard mask pattern 18M2 may have substantially the same width as that of the second wiring part 16L2.

The second hard mask pattern 18M2 may be used as an anti-reflective layer, an etch stop layer, or an anti-reflective layer and an etch stop layer in the manufacturing process. The second hard mask pattern 18M2 may include oxide, nitride, silicon oxynitride (SiON), carbon, or the like. As an example, the second hard mask pattern 18M2 may include silicon oxynitride (SiON) and may be used as an anti-reflective layer and an etch stop layer.

The second via part 16V2 may be connected to the second wiring part 16L2 through the second hard mask pattern 18M2. The second via part 16V2 may pass through the second hard mask pattern 18M2. The second via part 16V2 may have a plug shape having a plane such as a circular shape, an elliptical shape, or a polygonal shape.

The second interconnection structure IC2 may further include a third wiring part 16L3. The third wiring part 16L3 may be connected to the second via part 16V2. The third wiring part 16L3 may have a line shape extending in one direction.

The second interconnection structure IC2 may include the first wiring part 16L1, the first via part 16V1, the second wiring part 16L2, the second via part 16V2, and the third wiring part 16L3, or a combination thereof. As an example, the second interconnection structure IC2 may include the first wiring part 16L1, the first via part 16V1, the second wiring part 16L2, the second via part 16V2, and the third wiring part 16L3 that are sequentially stacked. The first wiring part 16L1, the second wiring part 16L2, and the third wiring part 16L3 may extend in parallel or intersect one another.

The first wiring part 16L1, the second wiring part 16L2, and the third wiring part 16L3 may have substantially the same height or different heights. As an example, a wiring part located at a relatively upper part may have a greater height than a wiring part located at a lower part. The first wiring part 16L1 may have a first height H1, the second wiring part 16L2 may have a second height H2, and the third wiring part 16L3 may have a third height H3. The second height H2 may be greater than the first height H1, and the third height H3 may be greater than the second height H2.

At least one of the first wiring part 16L1, the second wiring part 16L2, and the third wiring part 16L3 may include a seam S therein. The seam S may be caused in the process of depositing a conductive material. A portion where a deposition surface of a conductive layer deposited along an inner surface of a trench comes into contact may be the seam S.

The second interconnection structure IC2 may include a conductive material such as polysilicon or metal. As an example, the second interconnection structure IC2 may include a second barrier layer 17 and a second metal layer 16 located in the second barrier layer 17. In an embodiment, the second barrier layer 17 is for improving adhesion of the second metal layer 16 and may include metal nitride such as titanium nitride.

The second metal layer 16 may include the first wiring part 16L1, the first via part 16V1, the second wiring part 16L2, the second via part 16V2, and the third wiring part 16L3. Each of the first wiring part 16L1, the first via part 16V1, the second wiring part 16L2, the second via part 16V2, and the third wiring part 16L3 may be a part of the second metal layer 16. The first wiring part 16L1, the first via part 16V1, the second wiring part 16L2, the second via part 16V2, and the third wiring part 16L3 may be integrally connected to one another without an interface. The second metal layer 16 may include metal such as tungsten (W) or molybdenum (Mo).

The second barrier layer 17 may surround a bottom surface and sidewalls of the second metal layer 16. As an example, the second barrier layer 17 may surround a bottom surface and sidewalls of the first wiring part 16L1. The second barrier layer 17 may extend along an upper surface of the first wiring part 16L1, and might not be interposed between the first wiring part 16L1 and the first via part 16V1. The second barrier layer 17 may extend along sidewalls of the first via part 16V1. The second barrier layer 17 may extend along a bottom surface and sidewalls of the second wiring part 16L2 and might not be interposed between the first via part 16V1 and the second wiring part 16L2. The second barrier layer 17 may extend along an upper surface of the second wiring part 16L2, and might not be interposed between the second wiring part 16L2 and the second via part 16V2. The second barrier layer 17 may extend along sidewalls of the second via part 16V2. The second barrier layer 17 may extend along a bottom surface and sidewalls of the third wiring part 16L3, and might not be interposed between the second via part 16V2 and the third wiring part 16L3. The second barrier layer 17 may be interposed between the upper surface of the first wiring part 16L1 and the first hard mask pattern 18M1 and between the upper surface of the second wiring part 16L2 and the second hard mask pattern 18M2.

According to an embodiment described above, a plurality of wiring parts and a plurality of via parts may be formed at the same time, and the plurality of wiring parts and the plurality of via parts may each have a structure of a single layer. Accordingly, in an embodiment, the manufacturing cost can be reduced compared to a manufacturing method in which vias and wiring parts are separately formed. Furthermore, in an embodiment, stress due to process repetition can be reduced, and wafer warpage due to stress accumulation can be reduced.

The second interconnection structure IC2 may include one second barrier layer 17. The barrier layer may include a material having higher resistivity than a metal layer. Accordingly, in an embodiment, the second interconnection structure IC2 including one second barrier layer 17 may have lower contact resistance and lower line resistance than an interconnection structure in which vias and wiring parts each include a barrier layer. In an embodiment, operating characteristics of the semiconductor device can be improved through resistance reduction.

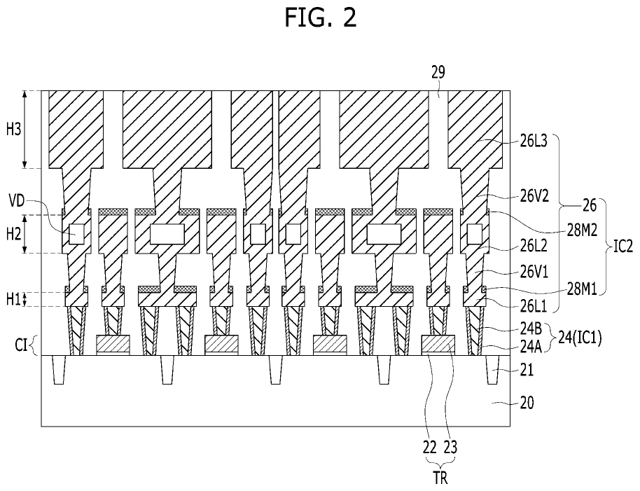

FIG. 2 is a diagram illustrating the structure of a semiconductor device in accordance with an embodiment. Hereinafter, the content overlapping with the previously described content will be omitted.

Referring to FIG. 2, the semiconductor device may include a first interconnection structure IC1 and a second interconnection structure IC2. The semiconductor device may further include a substrate 20, an isolation layer 21, a circuit CI, or an interlayer dielectric layer 29, or a combination thereof. The circuit CI may include a transistor TR, and the transistor TR may include a gate insulating layer 22 and a gate electrode 23.

The first interconnection structure IC1 may be located in the interlayer dielectric layer 29. The first interconnection structure IC1 may include a via 24, and the via 24 may include a first barrier layer 24A and a first metal layer 24B located in the first barrier layer 24A.

The second interconnection structure IC2 may be located in the interlayer dielectric layer 29. The second interconnection structure IC2 may be electrically connected to the first interconnection structure IC1. The second interconnection structure IC2 may include a first wiring part 26L1, a first via part 26V1, a second wiring part 26L2, a second via part 26V2, and a third wiring part 26L3, or a combination thereof. The second interconnection structure IC2 may further include a first hard mask pattern 28M1 or a second hard mask pattern 28M2, or a combination thereof.

The first wiring part 26L1, the second wiring part 26L2, and the third wiring part 26L3 may have substantially the same height or different heights. As an example, a wiring part located at a relatively upper part may have a greater height than a wiring part located at a lower part. The first wiring part 26L1 may have a first height H1, the second wiring part 26L2 may have a second height H2, and the third wiring part 26L3 may have a third height H3. The second height H2 may be greater than the first height H1, and the third height H3 may be greater than the second height H2.

At least one of the first wiring part 26L1, the second wiring part 26L2, and the third wiring part 26L3 may include a void VD therein. The void VD may be caused in the process of depositing a conductive material. In the deposition process, an empty space filled with no conductive material may remain inside the trench, and the empty space may be the void VD.

The second interconnection structure IC2 may include a second metal layer 26 and might not include a barrier layer. The first wiring part 26L1 may contact the first hard mask pattern 28M1, and the second wiring part 26L2 may contact the second hard mask pattern 28M2.

The second metal layer 26 may include metal such as tungsten (W) or molybdenum (Mo). As an example, the second metal layer 26 may include molybdenum (Mo). Because the molybdenum (Mo) does not use a fluorine-based source gas, even though a source gas remains in the void VD, a peripheral layer might not be damaged. Accordingly, when the second metal layer 26 is made of molybdenum (Mo), the second barrier layer may be omitted.

According to the structure described above, the second interconnection structure IC2 might not include a barrier layer. Accordingly, in an embodiment, contact resistance and line resistance of the second interconnection structure IC2 can be reduced.

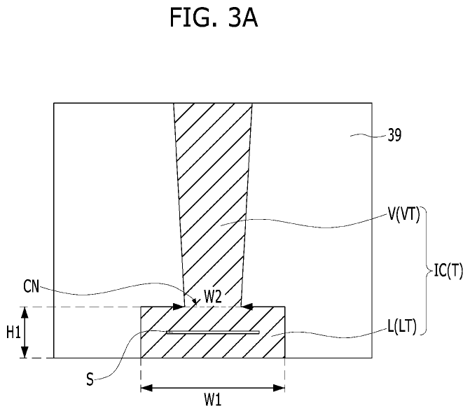

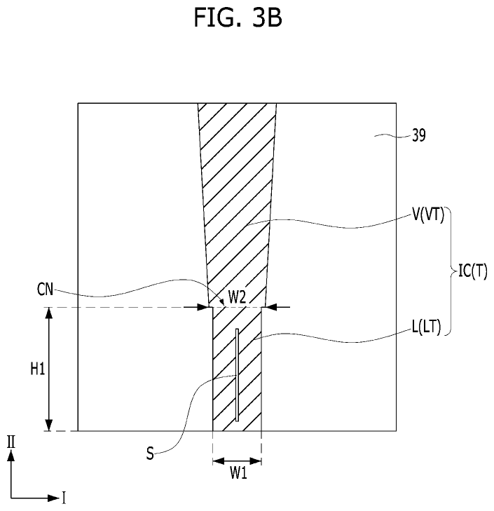

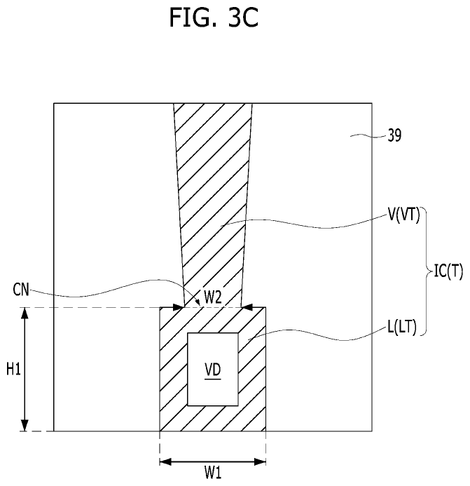

FIGS. 3A to 3C are diagrams illustrating the structure of a semiconductor device in accordance with an embodiment. Hereinafter, the content overlapping with the previously described content will be omitted.

Referring to FIGS. 3A to 3C, the semiconductor device may include an interconnection structure IC and an interlayer dielectric layer 39. The interconnection structure IC may include a wiring part L and a via part V. As an example, the interconnection structure IC may include a metal layer, and the metal layer may include the wiring part L and the via part V. The interconnection structure IC may or might not further include a barrier layer surrounding the metal layer.

The interlayer dielectric layer 39 may include a trench T, and the trench T may include a via trench VT and a wiring trench LT. The interconnection structure IC may be located in the trench T, the via part V may be located in the via trench VT, and the wiring part L may be located in the wiring trench LT.

The interconnection structure IC may be formed by supplying a source gas into the via trench VT and the wiring trench LT. The source gas may be supplied to the wiring trench LT through the via trench VT, and a conductive material may be deposited along inner surfaces of the via trench VT and the wiring trench LT.

The sizes of the wiring part L and the via part V may be determined in consideration of characteristics of the deposition process. In the deposition process, when a connection portion CN between the wiring trench LT and the via trench VT is clogged by a conductive material, because the source gas is no longer supplied into the wiring trench LT, a void may be caused in the wiring part L. Accordingly, in an embodiment, the sizes of the via part V and the wiring part L may be determined so that the source gas may be sufficiently supplied into the wiring trench LT.

Referring to FIG. 3A, the wiring part L may have a first width W1 and a first height H1. A bottom surface of the via part V may have a second width W2. The width of the bottom surface of the via part V may be a width of the connection portion CN. When the wiring part L has a varying width as in the case of a tapered shape, the first width W1 may be an average width, a minimum width, or a maximum width of the wiring part L.

The second width W2 may be greater than the first height H1. Through this, in an embodiment, it is possible to prevent or mitigate clogging of the connection portion CN before a deposition surface of the conductive material deposited on an upper surface of the wiring trench LT and a deposition surface of the conductive material deposited on a lower surface thereof come into contact with each other. The first width W1 may be greater than the first height H1 and the second width W2. According to such a structure, the wiring part L might not include a void. The wiring part L may include a seam S, and the seam S may extend in a horizontal direction.

Referring to FIG. 3B, the wiring part L may have the first width W1 and the first height H1. In an embodiment, the wiring part L may have the first width W1 in a first direction I and the first height H1 in the second direction. The first direction I may intersect the second direction II. The bottom surface of the via part V may have the second width W2. The second width W2 may be greater than the first width W1. Through this, in an embodiment, it is possible to prevent or mitigate clogging of the connection portion CN before a deposition surface of the conductive material deposited on one sidewall of the wiring trench LT and a deposition surface of the conductive material deposited on the other sidewall thereof come into contact with each other. The first height H1 may be greater than the first width W1 and the second width W2. According to such a structure, the wiring part L might not include a void. The wiring part L may include a seam S, and the seam S may extend in a vertical direction. In an embodiment, the seam S may extend in the second direction.

Referring to FIG. 3C, the wiring part L may have the first width W1 and the first height H1. The bottom surface of the via part V may have the second width W2. The first height H1 and the first width W1 may be greater than the second width W2. Through this, in an embodiment, the size of the wiring unit L may be increased, and contact resistance and line resistance of the interconnection structure IC may be reduced.

In an embodiment, as the size of the wiring trench LT increases, the connection portion CN may be clogged before the wiring trench LT is sufficiently filled with the conductive material, and the wiring part L may include a void VD. A source gas used when depositing a conductive material in the void VD may remain. Accordingly, in an embodiment, in order to reduce damage to a peripheral layer due to the remaining source gas, a source gas except for a fluorine-based source gas may be used. As an example, the conductive material may be molybdenum (Mo). When the metal layer of the interconnection structure IC includes molybdenum (Mo), the interconnection structure IC might not include a barrier layer.

According to the structure described above, the sizes of the wiring part L and the via part V may be determined in consideration of the characteristics of a deposition process, contact resistance, line resistance, materials of the interconnection structure IC, and the like. As an example, the sizes of the wiring part L and the via part V may be determined so that the wiring part L includes no void VD. In an embodiment, the sizes of the wiring part L and the via part V may be determined to reduce contact resistance or line resistance of the interconnection structure IC.

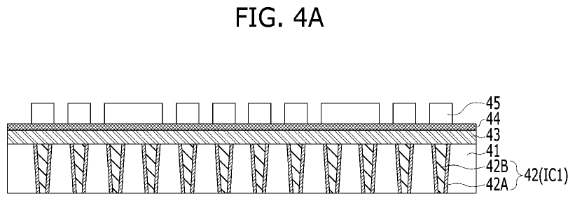

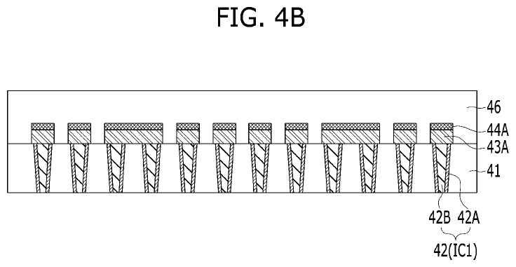

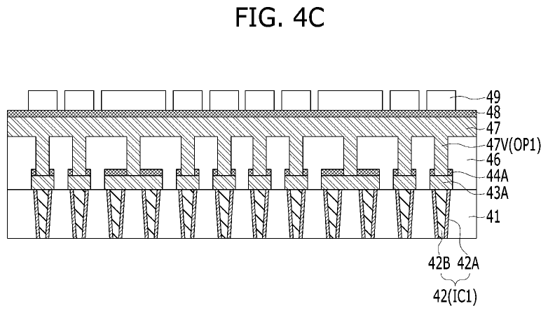

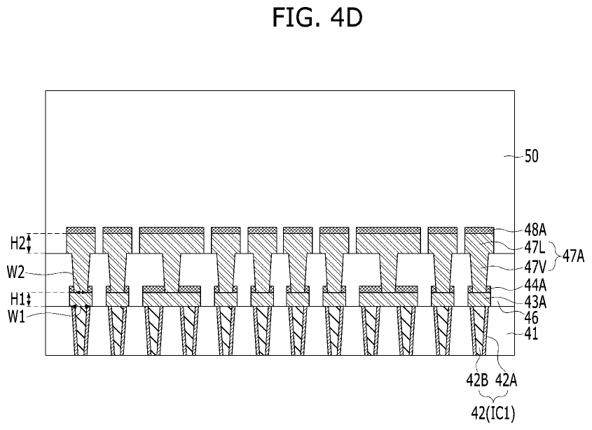

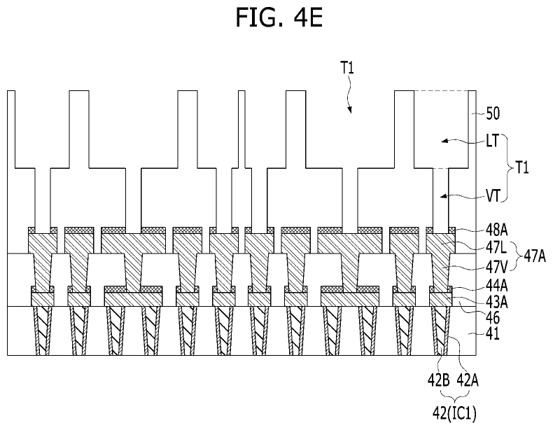

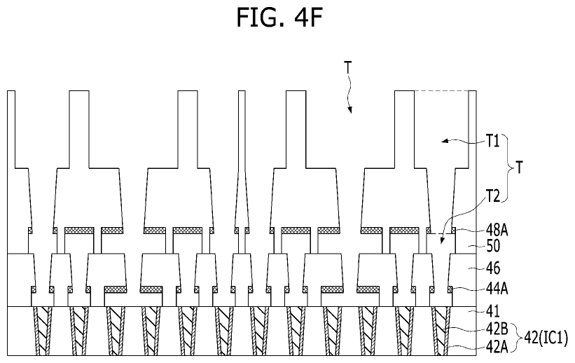

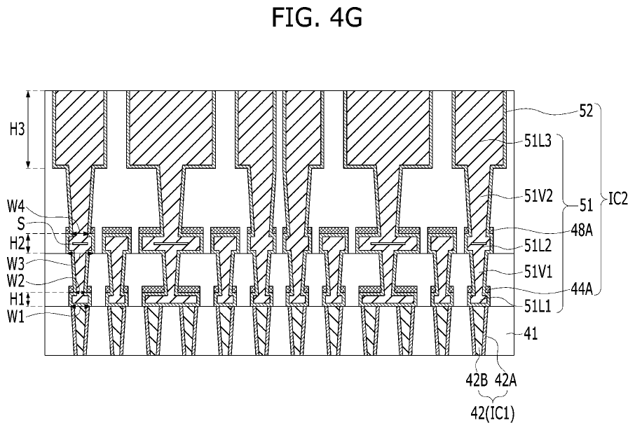

FIGS. 4A to 4G are diagrams for explaining a manufacturing method of a semiconductor device in accordance with an embodiment. Hereinafter, the content overlapping with the previously described content will be omitted.

Referring to FIG. 4A, a first interconnection structure IC1 may be formed in a first interlayer dielectric layer 41. The first interlayer insulating layer 41 may be a single layer or a multilayer, and may include an insulating material such as oxide. The first interconnection structure IC1 may include a via, or a wiring, or a combination thereof. As an example, the first interconnection structure IC1 may include a via 42 including a first barrier layer 42A and a first metal layer 42B in the first barrier layer 42A.

Subsequently, a first sacrificial layer 43 may be formed on the first interconnection structure IC1. The first sacrificial layer 43 is for defining a region where a first wiring part is to be formed, and may include a material having a high etching selectivity with respect to the first interlayer dielectric layer 41. As an example, the first sacrificial layer 43 may include a sacrificial material such as polysilicon, nitride, spin on carbon (SOC), or amorphous carbon.

Subsequently, a first hard mask layer 44 may be formed on the first sacrificial layer 43. The first hard mask layer 44 may include a material having a high etching selectivity with respect to the first sacrificial layer 43. As an example, the first hard mask layer 44 may include oxide, nitride, or silicon oxynitride, or a combination thereof. Subsequently, a first mask pattern 45 may be formed on the first hard mask layer 44. As an example, the first mask pattern 45 may include photoresist. The first hard mask layer 44 may be used as an anti-reflective layer in a lithography process using the first mask pattern 45.

Referring to FIG. 4B, the first hard mask layer 44 may be etched using the first mask pattern 45 as an etching barrier to form a first hard mask pattern 44A. Subsequently, the first sacrificial layer 43 may be etched using the first hard mask pattern 44A as an etching barrier to form a first sacrificial pattern 43A. Subsequently, a second interlayer dielectric layer 46 may be formed on the first sacrificial pattern 43A. The second interlayer dielectric layer 46 may be formed on the first interlayer dielectric layer 41 and the first hard mask pattern 44A.

Referring to FIG. 4C, a second sacrificial layer 47 may be formed on the second interlayer dielectric layer 46. The second sacrificial layer 47 may include a sacrificial via 47V connected to the first sacrificial pattern 43A through the second interlayer dielectric layer 46 and the first hard mask pattern 44A. As an example, the second sacrificial layer 47 may be formed after forming a first opening OP1 exposing the first sacrificial pattern 43A through the second interlayer dielectric layer 46. When forming the first opening OP1, the first hard mask pattern 44A may be used as an etch stop layer. When the first hard mask pattern 44A includes silicon oxynitride, the first hard mask layer 44 may be used as an anti-reflective layer and the first hard mask pattern 44A may be used as an etch stop layer. The first opening OP1 may be filled with the second sacrificial layer 47, and a filled portion in the first opening OP1 may be the sacrificial via 47V.

Subsequently, a second hard mask layer 48 may be formed on the second sacrificial layer 47. The second hard mask layer 48 may include a material having a high etching selectivity with respect to the second sacrificial layer 47. As an example, the second hard mask layer 48 may include oxide, nitride, or silicon oxynitride, or a combination thereof. Subsequently, a second mask pattern 49 may be formed on the second hard mask layer 48. As an example, the second mask pattern 49 may include photoresist. The second hard mask layer 48 may be used as an anti-reflective layer in a lithography process using the second mask pattern 49.

Referring to FIG. 4D, the second hard mask layer 48 may be etched using the second mask pattern 49 as an etching barrier to form a second hard mask pattern 48A. Subsequently, the second sacrificial layer 47 may be etched using the second hard mask pattern 48A as an etching barrier to form a second sacrificial pattern 47A. The second sacrificial pattern 47A may include a sacrificial via 47V and a sacrificial wiring 47L.

The first sacrificial pattern 43A may have a first width W1 and a first height H1. A bottom surface of the sacrificial via 47V may have a second width W2. As an example, the first width W1 may be greater than the first height H1, and the second width W2 may be greater than the first height H1. As an example, the first height H1 may be greater than the first width W1 and the second width W2 may be greater than the first width W1.

Subsequently, a third interlayer dielectric layer 50 may be formed on the second sacrificial pattern 47A. The third interlayer dielectric layer 50 may be formed on the second interlayer dielectric layer 46 and the second hard mask pattern 48A.

Referring to FIG. 4E, a first trench T1 may be formed in the third interlayer dielectric layer 50. The first trench T1 may include a via trench VT and a wiring trench LT. As an example, the via trench VT may be formed after the wiring trench LT is formed in the third interlayer dielectric layer 50. When the via trench VT is formed, the second hard mask pattern 48A may be used as an etch stop layer. As an example, when the second hard mask pattern 48A includes silicon oxynitride, the second hard mask layer 48 may be used as an anti-reflective layer and the second hard mask pattern 48A may be used as an etch stop layer. The via trench VT may be connected to the wiring trench LT and may expose the second sacrificial pattern 47A through the second hard mask pattern 48A. The via trench VT may extend from a bottom surface of the wiring trench LT.

Referring to FIG. 4F, a trench T may be formed by removing the second sacrificial pattern 47A and the first sacrificial pattern 43A. As an example, a second trench T2 may be formed by selectively etching the second sacrificial pattern 47A and the first sacrificial pattern 43A through the first trench T1. Through this, the trench T including the first trench T1 and the second trench T2 may be formed.

Referring to FIG. 4G, a second interconnection structure IC2 may be formed in the trench T. The second interconnection structure IC2 may include a second barrier layer 52 and a second metal layer 51. As an example, after the second barrier layer 52 is formed in the trench T, the second metal layer 51 may be formed in the second barrier layer 52. The second barrier layer 52 may be formed along an inner surface of the trench T. The second barrier layer 52 may have a thickness of 30 Å to 100 Å. A heat treatment process may be additionally performed after the second barrier layer 52 is formed.

The second interconnection structure IC2 may include a first wiring part 51L1, a first via part 51V1, a second wiring part 51L2, a second via part 51V2, and a third wiring part 51L3. The first wiring part 51L1 may be directly connected to the first interconnection structure IC1. The first via part 51V1 may be connected to the first wiring part 51L1 through the first hard mask pattern 44A. The second via part 51V2 may be connected to the second wiring part 51L2 through the second hard mask pattern 48A. The third wiring part 51L3 may be connected to the second via part 51V2. As an example, the second metal layer 51 may include the first wiring part 51L1, the first via part 51V1, the second wiring part 51L2, the second via part 51V2, and the third wiring part 51L3.

The first wiring part 51L1 may have a first height H1, the second wiring part 51L2 may have a second height H2, and the third wiring part 51L3 may have a third height H3. The second height H2 may be greater than the first height H1, and the third height H3 may be greater than the second height H2.

The first wiring part 51L1 may have the first width W1 and the first height H1. A bottom surface of the first via part 51V1 may have a second width W2. Referring to FIG. 3A described above, the second width W2 may be greater than the first height H1. Referring to FIG. 3B described above, the second width W2 may be greater than the first width W1.

The second wiring part 51L2 may have a third width W3 and a second height H2. A bottom surface of the second via part 51V2 may have a fourth width W4. Similar to FIG. 3A described above, the fourth width W4 may be greater than the second height H2. Similar to FIG. 3B described above, the fourth width W4 may be greater than the third width W3.

At least one of the first wiring part 51L1, the second wiring part 51L2, and the third wiring part 51L3 may include a seam S therein. As an example, the second wiring part 51L2 may include the seam S.

According to the manufacturing method described above, the second interconnection structure IC2 may be formed to include the plurality of wiring parts 51L1 to 51L3 and the plurality of via parts 51V1 and 51V2. Because the second interconnection structure IC2 is made of one second barrier layer 52 and one second metal layer 51, in an embodiment, the manufacturing cost can be reduced compared to a case where a barrier layer and a metal layer are formed a plurality of times. Furthermore, in an embodiment, stress due to process repetition can be reduced and wafer warpage due to stress accumulation can be reduced.

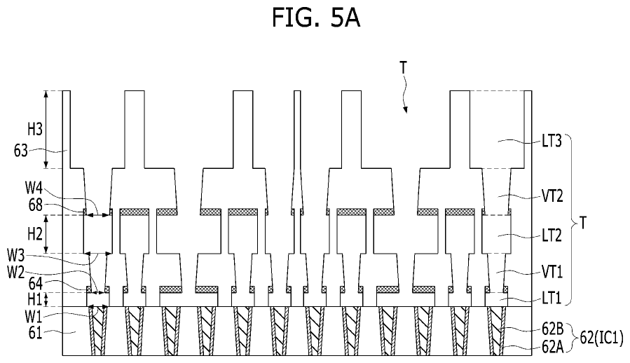

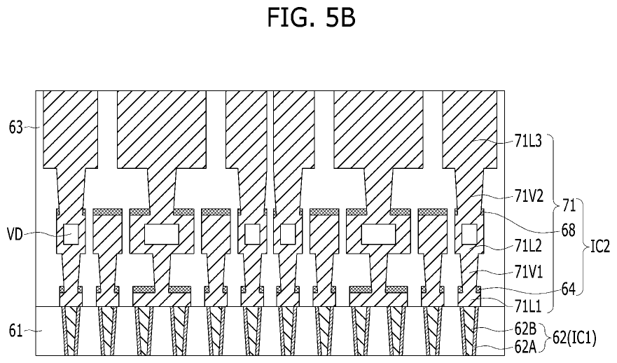

FIGS. 5A and 5B are diagrams for explaining a manufacturing method of a semiconductor device in accordance with an embodiment. Hereinafter, the content overlapping with the previously described content will be omitted.

Referring to FIG. 5A, a first interconnection structure IC1 may be formed in a first interlayer dielectric layer 61. The first interconnection structure IC1 may include a via, or a wire, or a combination thereof. As an example, the first interconnection structure IC1 may include a via 62 including a first barrier layer 62A and a first metal layer 62B.

Subsequently, a second interlayer dielectric layer 63 including a trench T may be formed. The second interlayer insulating layer 63 may be a single layer or a multilayer. The trench T may include a first line trench LT1, a first via trench VT1, a second line trench LT2, a second via trench VT2, or a third line trench LT3, or a combination thereof. The first via trench VT1 may be connected to the first line trench LT1 through a first hard mask pattern 64. The second via trench VT2 may be connected to the second line trench LT2 through a second hard mask pattern 68. As an example, the trench T may be formed in the second interlayer insulating layer 63 by using the manufacturing method previously described with reference to FIGS. 4A to 4F.

The first line trench LT1 may have a first height H1, the second line trench LT2 may have a second height H2, and the third line trench LT3 may have a third height H3. The second height H2 may be greater than the first height H1, and the third height H3 may be greater than the second height H2.

The first line trench LT1 may have the first width W1 and the first height H1. A bottom surface of the first via trench VT1 may have a second width W2. Similar to FIG. 3C described above, the first height H1 and the first width W1 may be greater than the second width W2.

The second line trench LT2 may have a third width W3 and the second height H2. A bottom surface of the second via trench VT2 may have a fourth width W4. Similar to FIG. 3C described above, the second height H2 and the third width W3 may be greater than the fourth width W4.

Referring to FIG. 5B, a second interconnection structure IC2 may be formed in the trench T. The second interconnection structure IC2 may include a second metal layer 71 and might not include a second barrier layer.

The second interconnection structure IC2 may include a first wiring part 71L1, a first via part 71V1, a second wiring part 71L2, a second via part 71V2, and a third wiring part 71L3, or a combination thereof. The first wiring part 71L1 may be connected to the first interconnection structure IC1. The first via part 71V1 may be connected to the first wiring part 71L1 through the first hard mask pattern 64. The second via part 71V2 may be connected to the second wiring part 71L2 through the second hard mask pattern 68. The third wiring part 71L3 may be connected to the second via part 71V2. As an example, the second metal layer 71 may include the first wiring part 71L1, the first via part 71V1, the second wiring part 71L2, the second via part 71V2, and the third wiring part 71L3.

At least one of the first wiring part 71L1, the second wiring part 71L2, and the third wiring part 71L3 may include a void VD therein. As an example, the second wiring part 71L2 may include a void VD. A source gas used when depositing the second metal layer 71 may remain in the void VD. As an example, the second metal layer 71 may include molybdenum (Mo) and may be formed using a source gas other than a fluorine-based source gas. Accordingly, in an embodiment, even though the source gas remains in the void VD, damage to a peripheral layer can be prevented or reduced. Furthermore, in an embodiment, when the second metal layer 71 is formed, step coverage can be improved.

According to the manufacturing method described above, the second interconnection structure IC2 can be made of the second metal layer 71. In an embodiment, the second interconnection structure IC2 can be formed without a barrier layer, and the manufacturing cost can be reduced.

Although embodiments according to the technical idea of the present disclosure have been described above with reference to the accompanying drawings, this is only for explaining the embodiments according to the concept of the present disclosure, and the present disclosure is not limited to the above embodiments. Various types of substitutions, modifications, and changes for the embodiments may be made by those skilled in the art, to which the present disclosure pertains, without departing from the technical idea of the present disclosure defined in the following claims, and it should be construed that these substitutions, modifications, and changes belong to the scope of the present disclosure.

What is claimed is:

1. A semiconductor device comprising:
a first interconnection structure; and
a second interconnection structure including a first wiring part electrically connected to the first interconnection structure, a first hard mask pattern on the first wiring part, and a first via part connected to the first wiring part through the first hard mask pattern.

2. The semiconductor device of claim 1, wherein the second interconnection structure comprises:
a barrier layer; and
a metal layer located in the barrier layer and including the first wiring part and the first via part.

3. The semiconductor device of claim 2, wherein the barrier layer includes metal nitride and the metal layer includes tungsten (W).

4. The semiconductor device of claim 1, wherein the second interconnection structure includes a metal layer including the first wiring part contacting the first hard mask pattern and the first via part.

5. The semiconductor device of claim 4, wherein the metal layer includes molybdenum (Mo).

6. The semiconductor device of claim 1, wherein the first wiring part has a first width and a first height, a bottom surface of the first via part has a second width, and the second width is greater than the first height.

7. The semiconductor device of claim 1, wherein the first wiring part has a first width and a first height, a bottom surface of the first via part has a second width, and the second width is greater than the first width.

8. The semiconductor device of claim 1, wherein the first wiring part has a first width and a first height, a bottom surface of the first via part has a second width, and the first width and the first height are greater than the second width.

9. The semiconductor device of claim 8, wherein the first wiring part includes a void.

10. The semiconductor device of claim 1, wherein the second interconnection structure further comprises:
a second wiring part connected to the first wiring part;
a second hard mask pattern on the second wiring part; and
a second via part connected to the second wiring part through the second hard mask pattern.

11. The semiconductor device of claim 10, wherein the second wiring part has a greater height than the first wiring part.

12. The semiconductor device of claim 11, wherein the second wiring part includes a void therein.

13. The semiconductor device of claim 10, wherein the second interconnection structure further includes a third wiring part connected to the second via part.

14. The semiconductor device of claim 13, wherein the third wiring part has a greater height than the second wiring part.

15. The semiconductor device of claim 13, wherein the second interconnection structure comprises:
a barrier layer; and
a metal layer located in the barrier layer and including the first wiring part, the first via part, the second wiring part, the second via part, and the third wiring part.

16. The semiconductor device of claim 13, wherein the second interconnection structure includes a metal layer including the first wiring part contacting the first hard mask pattern, the first via part, the second wiring part contacting the second hard mask pattern, the second via part, and the third wiring part.

17. The semiconductor device of claim 1, further comprising:
a circuit electrically connected to the first interconnection structure.
